(19) United States
(12) Patent Application Publication
(10) Pub. No.: US 2025/0210114 A1
(43) Pub. Date: Jun. 26, 2025

(54) SEMICONDUCTOR DEVICE AND OPERATING METHOD OF SEMICONDUCTOR DEVICE

(71) Applicant: SK hynix Inc., Gyeonggi-do (KR)

(72) Inventor: Sung Hyun HWANG, Gyeonggi-do (KR)

(21) Appl. No.: 18/616,177

(22) Filed: Mar. 26, 2024

(30) Foreign Application Priority Data
Dec. 21, 2023 (KR) 10-2023-0188061

(51) Int. Cl. G11C 16/26; G11C 11/56; G11C 16/04; G11C 16/10

(52) U.S. Cl. CPC G11C 16/26; G11C 16/0483; G11C 11/5642; G11C 16/10

(57) ABSTRACT

A semiconductor device may include at least one memory string that is connected between a bit line and a source line and includes a plurality of memory cells connected to a plurality of word lines, and a page buffer connected to the bit line and configured to sense data stored in the plurality of memory cells. Multi-bit data stored in a selected memory cell of the plurality of memory cells may be consecutively output by sequentially providing a selected word line of the plurality of word lines with read voltages having different levels in a state in which unselected word lines of the plurality of word lines are provided with a pass voltage.

### CROSS-REFERENCE TO RELATED APPLICATION

The present application claims priority under 35 U.S.C. § 119 to Korean Patent Application No. 10-2023-0188061 filed on Dec. 21, 2023, which is incorporated herein by reference in its entirety.

### BACKGROUND

### 1. Technical Field

Embodiments of the present disclosure relate to an integrated circuit technology and, more particularly, to a semiconductor device and an operating method of the semiconductor device.

### 2. Related Art

Recently, as various electronic devices are being reduced in size, have low power consumption, and high performance, a semiconductor device capable of storing information is required for the various electronic devices, such as computers and portable communication devices. The semiconductor device may be a volatile memory device or a nonvolatile memory device. The volatile memory device has a high data processing speed, but has a disadvantage in that the volatile memory device needs to be continuously supplied with power in order to retain data that has been stored in the volatile memory device. The nonvolatile memory device does not need to be continuously supplied with power in order to retain data that has been stored in the nonvolatile memory device, but has a disadvantage in that the nonvolatile memory device has a low data processing speed.

The nonvolatile memory device performs a program operation in order to store data therein, and performs an erase operation in order to erase data stored therein. Furthermore, the nonvolatile memory device performs an operation of verifying whether data have been programmed or erased normally after the start of the program operation or the erase operation and a read operation for outputting programmed data.

Accordingly, in order to improve the data processing speed of the nonvolatile memory device, research for reducing the time taken for a verification operation or a read operation in addition to research for reducing the time taken for a program or erase operation continues.

### SUMMARY

In an embodiment of the present disclosure, a semiconductor device may include at least one memory string that is connected between a bit line and a source line and includes a plurality of memory cells connected to a plurality of word lines, and a page buffer connected to the bit line and configured to sense data stored in the plurality of memory cells. Multi-bit data stored in a selected memory cell of the plurality of memory cells may be consecutively output by sequentially providing a selected word line of the plurality of word lines with read voltages having different levels in a state in which unselected word lines of the plurality of word lines are provided with a pass voltage.

In an embodiment of the present disclosure, an operating method of a semiconductor device may include receiving a read command that instructs to consecutively output multi-bit data stored in a memory cell of a memory string coupled to a plurality of word lines, providing a pass voltage to unselected word lines of the plurality of word lines until an operation corresponding to the read command is completed, and sequentially providing a selected word line of the plurality of word lines with read voltages having different levels to sequentially determine the multi-bit data.

In an embodiment of the present disclosure, an operating method of a semiconductor device may include receiving a read command, checking that the read command is received prior to a check point, outputting data sensed in a previous read command in response to the checked reception of the read command being checked to have been received, and sensing data by sequentially providing a selected word line with read voltages having different levels in response to the checked reception of the read command.

### BRIEF DESCRIPTION OF THE DRAWINGS

FIG. 1 is a diagram illustrating a configuration of a semiconductor device according to an embodiment of the present disclosure.

FIG. 2 is a diagram illustrating a configuration of a memory block according to an embodiment of the present disclosure.

FIG. 3 is a diagram illustrating a configuration of a page buffer according to an embodiment of the present disclosure.

FIGS. 4 to 9 are diagrams for describing an operation of the semiconductor device according to an embodiment of the present disclosure.

FIG. 10 is a diagram illustrating a configuration of a semiconductor device according to another embodiment of the present disclosure.

FIG. 11 is a diagram for describing an operation of the semiconductor device according to another embodiment of the present disclosure.

### DETAILED DESCRIPTION

Hereinafter, embodiments according to the technical spirit of the present disclosure are described with reference to the accompanying drawings.

Embodiments of the present disclosure may provide a semiconductor device for reducing the time taken for a read operation and an operating method of the semiconductor device.

It is possible to improve the data processing speed of a semiconductor device by reducing the time taken to read a memory cell in which multiple bits are stored.

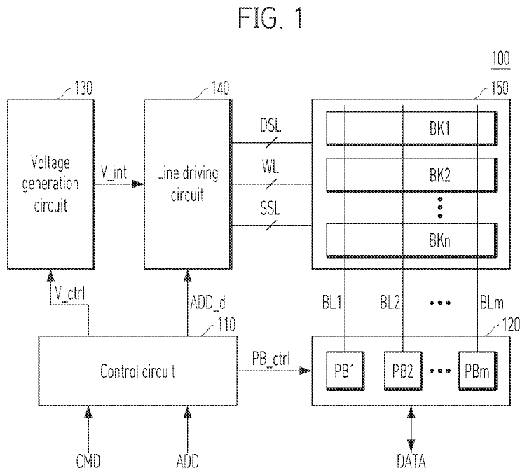

FIG. 1 is a diagram illustrating a configuration of a semiconductor device 100 according to an embodiment of the present disclosure.

Referring to FIG. 1, the semiconductor device 100 may include a control circuit 110, a page buffer group 120, a voltage generation circuit 130, a line driving circuit 140, and a memory cell array 150.

The control circuit 110 may program data into the memory cell array 150 or may erase data that have been programmed into the memory cell array 150 by controlling the page buffer group 120, the voltage generation circuit 130, and the line driving circuit 140. Furthermore, the control circuit 110 may sense data that have been stored in the memory cell array 150 or output the sensed data by controlling the page buffer group 120, the voltage generation circuit 130, and the line driving circuit 140.

For example, the control circuit 110 may generate a page buffer control signal PB_ctrl based on a command signal CMD and an address signal ADD that are received from the outside (e.g., a host), and may provide the page buffer control signal PB_ctrl to the page buffer group 120.

The control circuit 110 may generate a voltage control signal V_ctrl based on the command signal CMD, and may provide the voltage control signal V_ctrl to the voltage generation circuit 130.

The control circuit 110 may generate a driving address signal ADD_d based on the command signal CMD and the address signal ADD, and may provide the driving address signal ADD_d to the line driving circuit 140.

The page buffer group 120 may include a plurality of page buffers PB1, PB2, . . . , PBm. The plurality of page buffers PB1, PB2, . . . , PBm may be connected to a plurality of bit lines BL1, BL2, . . . , BLm, where m is a natural number, respectively. The plurality of page buffers PB1, PB2, . . . , PBm may each sense a data value that has been stored in a memory cell through a bit line, and may output the sensed value as data DATA.

The voltage generation circuit 130 may generate internal voltages V_int having various voltage levels based on the voltage control signal V_ctrl, and may provide the internal voltages V_int to the line driving circuit 140. For example, the voltage generation circuit 130 may generate the internal voltages V_int having different voltage levels, such as a program voltage, a read voltage, and a pass voltage, based on the voltage control signal V_ctrl, and may provide the generated internal voltages V_int to the line driving circuit 140.

The line driving circuit 140 may drive drain selection lines DSL, word lines WL, and source selection lines SSL to the voltage levels of the internal voltages V_int based on the driving address signal ADD_d. For example, the line driving circuit 140 may drive at least one of the drain selection lines DSL, the word lines WL, and the source selection lines SSL to the voltage levels of the internal voltages V_int based on the driving address signal ADD_d. More specifically, for example, the line driving circuit 140 may drive at least one of the drain selection lines DSL and at least one of the source selection lines SSL to the voltage level of a pass voltage after the start of a read operation. Furthermore, the line driving circuit 140 may drive at least one of the word lines WL to the voltage level of a read voltage and drive the remaining word lines to the voltage level of a pass voltage after the start of a read operation.

The memory cell array 150 may include a plurality of memory blocks BK1, BK2, . . . , BKn, where n is a natural number. The plurality of memory blocks BK1, BK2, . . . , BKn may each be selected by the word lines WL. The memory strings of a selected memory block may be connected to the plurality of page buffers PB1, PB2, . . . , PBm through the bit lines BL1, BL2, . . . , BLm. Furthermore, the plurality of memory blocks BK1, BK2, . . . , BKn may each include a plurality of memory strings in each of which a plurality of memory cells have been connected in series. The plurality of memory strings may each include a first selection transistor (e.g., a drain selection transistor), a second selection transistor (e.g., a source selection transistor), and a dummy cell in addition to the plurality of memory cells that are connected in series. The first selection transistor may be configured to be turned on or turned off by the drain selection line DSL. The second selection transistor may be configured to be turned on or turned off by the source selection line SSL.

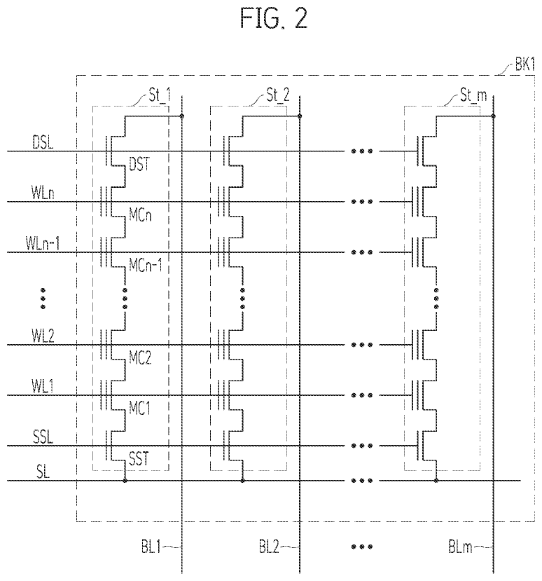

FIG. 2 is a diagram illustrating a configuration of a memory block according to an embodiment of the present disclosure.

FIG. 2 may illustrate a memory block BK1, among the plurality of memory blocks BK1, BK2, . . . , BKn that are included in the memory cell array 150 of FIG. 1.

Referring to FIG. 2, the memory block BK1 may include a plurality of memory strings St_1 to St_m that are connected between the plurality of bit lines BL1 to BLm, respectively, and a source line SL. The plurality of memory strings St_1 to St_m may each include at least one drain selection transistor DST, a plurality of memory cells MC1 to MCn, and at least one source selection transistor SST. For example, a first memory string St_1 may include a drain selection transistor DST, a plurality of memory cells MC1 to MCn, and a source selection transistor SST that are connected in series between a first bit line BL1 and the source line SL. The drain selection transistor DST may be configured to be turned on or turned off by the drain selection line DSL. The source selection transistor SST may be configured to be turned on or turned off by the source selection line SSL. Furthermore, the plurality of memory cells MC1 to MCn may be configured to be controlled by a plurality of word lines WL1 to WLn, respectively.

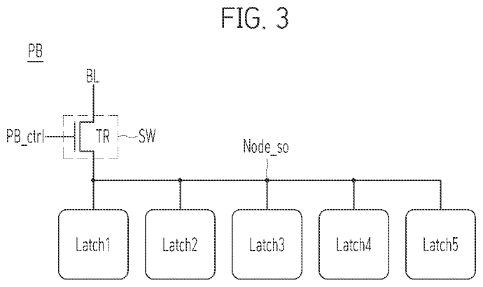

FIG. 3 is a diagram illustrating a configuration of a page buffer according to an embodiment of the present disclosure.

FIG. 3 may illustrate a construction of one page buffer PB, among the plurality of page buffers PB1 to PBm that are included in the page buffer group 120 of FIG. 1.

Referring to FIG. 3, the page buffer PB may include a plurality of latches Latch1 to Latch5. Furthermore, the page buffer PB may further include at least one switch SW. The plurality of latches Latch1 to Latch5 may be configured to be connected to a common node Node_so in common. The switch SW may be configured to connect or separate the bit line BL and the common node Node_so based on the page buffer control signal PB_ctrl.

When the bit line BL and the common node Node_so are connected, the page buffer PB may sense a current or voltage of the bit line BL and store a sensed value by using one of the plurality of latches Latch1 to Latch5. The plurality of latches Latch1 to Latch5 may store a value sensed from the bit line BL after the start of a read operation, and may move the stored value to another latch based on the page buffer control signal PB_ctrl.

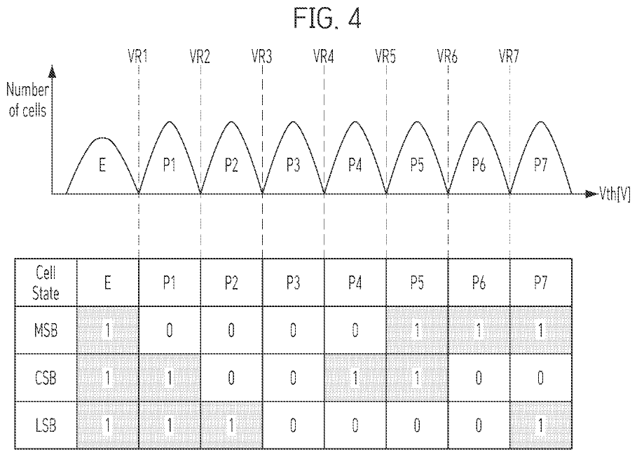

FIGS. 4 to 9 are diagrams for describing an operation of the semiconductor device according to an embodiment of the present disclosure.

FIG. 4 is a diagram for describing program states of memory cells in each of which multi-bit data are stored and read operations for the memory cells. In this case, FIG. 4 may illustrate an example of a memory cell capable of storing 3-bit data in order to describe the program state of the memory cell in which multi-bit data are stored.

Referring to FIG. 4, the memory cell may store 3-bit data. For example, the memory cell may store a most significant bit (MSB), a central significant bit (CSB), and a least significant bit (LSB). The state of the memory cell may transition to an erase state E, a first program state P1, a second program state P2, a third program state P3, a fourth program state P4, a fifth program state P5, a sixth program state P6, and a seventh program state P7 depending on a data value of each of the MSB, the CSB, and the LSB. The erase state E may correspond to a case in which all of the MSB, the CSB, and the LSB have a digital logic value 1. The first program state P1 may correspond to a case in which the MSB has a digital logic value 0 and the CSB and the LSB have a digital logic value 1. The second program state P2 may correspond to a case in which the MSB and the CSB have a digital logic value 0 and the LSB has a digital logic value 1. The third program state P3 may correspond to a case in which all of the MSB, the CSB, and the LSB have a digital logic value 0. The fourth program state P4 may correspond to a case in which the MSB and the LSB have a digital logic value 0 and the CSB has a digital logic value 1. The fifth program state P5 may correspond to a case in which the MSB and the CSB have a digital logic value 1 and the LSB has a digital logic value 0. The sixth program state P6 may correspond to a case in which the MSB has a digital logic value 1 and the CSB and the LSB have a digital logic value 0. The seventh program state P7 may correspond to a case in which the MSB and the LSB have a digital logic value 1 and the CSB has a digital logic value 0.

Furthermore, in a distribution of the threshold voltages Vth of memory cells having the erase state E and the first to seventh program states P1, P2, P3, P4, P5, P6, and P7, the erase state E may correspond to a distribution of threshold voltages having the lowest level. Furthermore, a distribution of the threshold voltages Vth of memory cells having the first to seventh program states P1, P2, P3, P4, P5, P6, and P7 may have a sequentially increasing value. That is, a distribution of the threshold voltages of memory cells having the first program state P1, among the first to seventh program states P1, P2, P3, P4, P5, P6, and P7, may be the lowest. A distribution of the threshold voltages of memory cells having the seventh program state P7, among the first to seventh program states P1, P2, P3, P4, P5, P6, and P7, may be the highest.

A first read voltage VR1 may be a voltage for determining the erase state E and the first program state P1, and may be a voltage having a level corresponding to a level between a maximum value of a distribution of threshold voltages corresponding to the erase state E and a minimum value of a distribution of threshold voltages corresponding to the first program state P1.

A second read voltage VR2 may be a voltage for determining the first program state P1 and the second program state P2, and may be a voltage having a level corresponding to a level between a maximum value of a distribution of threshold voltages corresponding to the first program state P1 and a minimum value of a distribution of threshold voltages corresponding to the second program state P2.

A third read voltage VR3 may be a voltage for determining the second program state P2 and the third program state P3, and may be a voltage having a level corresponding to a level between a maximum value of a distribution of threshold voltages corresponding to the second program state P2 and a minimum value of a distribution of threshold voltages corresponding to the third program state P3.

A fourth read voltage VR4 may be a voltage for determining the third program state P3 and the fourth program state P4, and may be a voltage having a level corresponding to a level between a maximum value of a distribution of threshold voltages corresponding to the third program state P3 and a minimum value of a distribution of threshold voltages corresponding to the fourth program state P4.

A fifth read voltage VR5 may be a voltage for determining the fourth program state P4 and the fifth program state P5, and may be a voltage having a level corresponding to a level between a maximum value of a distribution of threshold voltages corresponding to the fourth program state P4 and a minimum value of a distribution of threshold voltages corresponding to the fifth program state P5.

A sixth read voltage VR6 may be a voltage for determining the fifth program state P5 and the sixth program state P6, and may be a voltage having a level corresponding to a level between a maximum value of a distribution of threshold voltages corresponding to the fifth program state P5 and a minimum value of a distribution of threshold voltages corresponding to the sixth program state P6.

A seventh read voltage VR7 may be a voltage for determining the sixth program state P6 and the seventh program state P7, and may be a voltage having a level corresponding to a level between a maximum value of a distribution of threshold voltages corresponding to the sixth program state P6 and a minimum value of a distribution of threshold voltages corresponding to the seventh program state P7.

Accordingly, a voltage having the lowest level, among the first to seventh read voltages VR1, VR2, VR3, VR4, VR5, VR6, and VR7, may be the first read voltage VR1. A voltage having the highest level, among the first to seventh read voltages VR1, VR2, VR3, VR4, VR5, VR6, and VR7, may be the seventh read voltage VR7. Furthermore, the first to seventh read voltages VR1, VR2, VR3, VR4, VR5, VR6, and VR7 may each be a voltage the level of which sequentially rises.

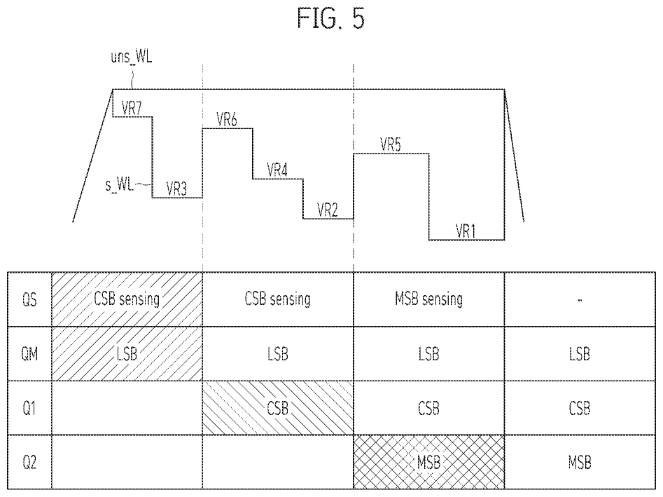

FIG. 5 is a diagram for describing an operation of reading data of a memory cell in which 3-bit data have been stored. This case may be a case in which the semiconductor device has received a read command that instructs to consecutively output data of the LSB, the CSB, and the MSB that have been stored in the memory cell. In FIG. 5, as an example, the first memory string St_1 of FIG. 2 has been selected.

Referring to FIG. 2, the first bit line BL1, among the plurality of bit lines BL1 to BLm, may be provided with a voltage having a higher voltage level than a ground voltage. The remaining bit lines BL2 to BLm may be provided with the ground voltage. Furthermore, the drain selection transistor DST and source selection transistor SST of the first memory string St_1 may be turned on by the drain selection line DSL and the source selection line SSL. At least one of the plurality of word lines WL1 to WLn may be selected. The selected word line may be provided with a read voltage, and unselected word lines may be provided with a pass voltage. In this case, as illustrated in FIGS. 4 and 5, the read voltage may include the first to seventh read voltages VR1, VR2, VR2, VR3, VR4, VR5, VR6, and VR7.

Referring to FIG. 3, the bit line BL, that is, the first bit line BL1, and the page buffer PB (PB1 in FIG. 1) may be electrically connected by the switch SW. That is, the first bit line BL1 and the common node Node_so may be electrically connected.

Referring to FIGS. 3 and 5, the first latch Latch1 may sense a data value that has been stored in a memory cell that belongs to the first memory string St_1 and that is connected to a selected word line s_WL based on a voltage or current of the first bit line BL1. In this case, the first latch Latch1 may play a role as a latch QS for sensing.

The second to fourth latches Latch2, Latch3, and Latch4 may store data that have been sensed from the first latch Latch1, that is, the latch QS for sensing. In this case, the second to fourth latches Latch2, Latch3, and Latch4 may play roles as latches QM, Q1, and Q2 for storage, respectively.

The fifth latch Latch5 may play a role as a cache latch Qc that receives data that have been stored in the latches QM, Q1, and Q2 for storage and that outputs the received data to the outside of the page buffer PB.

An operation of consecutively sensing and outputting data of the LSB, the CSB, and the MSB that have been stored in a memory cell is described more specifically as follows with reference to FIG. 5.

Unselected word lines uns_WL may be provided with a pass voltage.

The selected word line s_WL may be sequentially provided with the seventh read voltage VR7 and the third read voltage VR3 in order to determine the LSB. In this case, when the seventh and third read voltages VR7 and VR3 are sequentially provided to the selected word line s_WL, the latch QS for sensing may sense the LSB of the memory cell that has been connected to the selected word line s_WL through the bit line BL1. Thereafter, the LSB that has been sensed by the latch QS for sensing may be stored in the latch QM for storage.

While the pass voltage is provided to the unselected word lines uns_WL, the LSB may be stored in the latch QM for storage, and the sixth read voltage VR6, the fourth read voltage VR4, and the second read voltage VR2 may be sequentially provided to the selected word line s_WL. At this time, the latch QS for sensing may sense the CSB of the memory cell that has been connected to the selected word line s_WL through the bit line BL1. Thereafter, the CSB that has been sensed by the latch QS for sensing may be stored in the latch Q1 for storage.

While the pass voltage is provided to the unselected word lines uns_WL, the CSB may be stored in the latch Q1 for storage, and the fifth read voltage VR5 and the first read voltage VR1 may be sequentially provided to the selected word line s_WL. At this time, the latch QS for sensing may sense the MSB of the memory cell that has been connected to the selected word line s_WL through the bit line BL1. Thereafter, the MSB that has been sensed by the latch QS for sensing may be stored in the latch Q2 for storage.

As described above, when receiving a read command that instructs to consecutively output multi-bit data that have been stored in a multi-bit memory cell, the semiconductor device according to an embodiment of the present disclosure may sequentially provide a selected word line with read voltages having different levels while providing a pass voltage to unselected word lines, may sense the multi-bit data of the memory cell, and may store the multi-bit data in a page buffer. Thereafter, the semiconductor device may output the multi-bit data that have been stored in the page buffer to the outside of the page buffer.

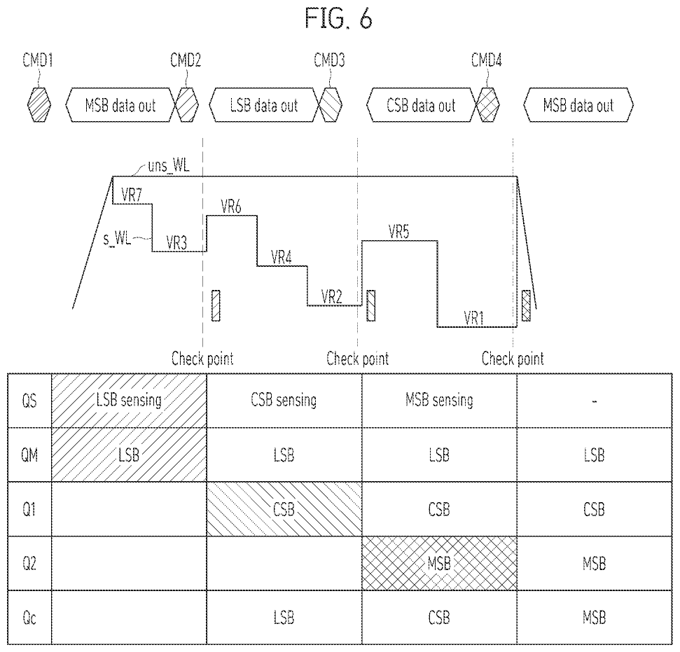

FIG. 6 is a diagram for describing an operation of reading data of a memory cell in which 3-bit data have been stored. This case may be a case in which the semiconductor device has consecutively received read commands to output data of the LSB, the CSB, and the MSB that have been stored in a memory cell.

A first read command CMD1 may be a command including a command that instructs to read the LSB of a currently selected memory cell and a command that instructs to output the sensed MSB of a previous memory cell. A second read command CMD2 may be a command including a command that instructs to read the CSB of a currently selected memory cell and a command that instructs to output the sensed LSB of a previous memory cell. A third read command CMD3 may be a command including a command that instructs to read the MSB of a currently selected memory cell and a command that instructs to output the sensed CSB of a previous memory cell. Subsequently, a command including a command that instructs to read the LSB of a next selected memory cell and a command that instructs to output the sensed MSB of a previous memory cell output may be received through a fourth read command CMD4.

When the first read command CMD1 is received, a currently selected word line s_WL may be sequentially provided with the seventh read voltage VR7 and the third read voltage VR3. At this time, the unselected word lines uns_WL may be provided with a pass voltage. Furthermore, the sensed MSB of a previous memory cell may be output from the cache latch Qc. The LSB of a currently selected memory cell may be sensed by the latch QS for sensing, and may be stored in the latch QM for storage.

The second read command CMD2 may be received prior to the first check point. When the second read command CMD2 is received prior to the first check point, the pass voltage may be continuously provided to the unselected word lines uns_WL. The selected word line s_WL may be sequentially provided with the sixth read voltage VR6, the fourth read voltage VR4, and the second read voltage VR2 for determining the CSB of the currently selected memory cell. At this time, after the first check point, the LSB that has been stored in the latch QM for storage may be moved to the cache latch Qc and output to the outside of the page buffer PB. Furthermore, the CSB of the currently selected memory cell may be sensed by the latch QS for sensing and stored in the latch Q1 for storage.

The third read command CMD3 may be received prior to the second check point. When the third read command CMD3 is received prior to the second check point, the unselected word lines uns_WL may be continuously provided with the pass voltage. The selected word line s_WL may be sequentially provided with the fifth read voltage VR5 and the first read voltage VR1 for determining the MSB of the currently selected memory cell. At this time, after the second check point, the CSB that has been stored in the latch Q1 for storage may be moved to the cache latch Qc and output to the outside of the page buffer PB. Furthermore, the MSB of the currently selected memory cell may be sensed by the latch QS for sensing and stored in the latch Q2 for storage.

The fourth read command CMD4 may be received prior to the third check point. When the fourth read command CMD4 is received prior to the third check point, the voltage levels of the currently selected word line s_WL and the unselected word lines uns_WL may be precharged to a specific voltage level. Furthermore, a next selected word line may be sequentially provided with at least one of the first to seventh read voltages VR1 to VR7, and unselected word lines may be provided with a pass voltage. Furthermore, the MSB of a currently selected memory cell, which has been stored in the latch Q2 for storage, may be moved to the cache latch Qc and output to the outside of the page buffer PB.

As described above, in a read operation of the semiconductor device according to an embodiment of the present disclosure, when multiple bits stored in one memory cell are sequentially output by a read command that has been received prior to each check point, a pass voltage may be continuously provided to unselected word lines without precharging word lines, and read voltages for determining each of the multiple bits may be sequentially provided to a selected word line. Furthermore, the latch for sensing may sense data by the read command that has been received prior to the check point, and the sensed data may be stored in the latch for storage and output. Accordingly, multi-bit data stored in a memory cell can be sequentially read.

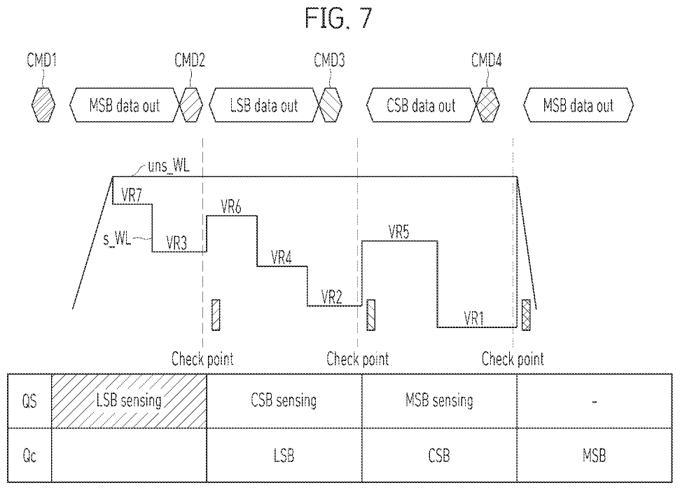

FIG. 7 is a diagram for describing an operation of reading data of a memory cell in which multi-bit data have been stored as illustrated in FIG. 6. In this case, FIG. 6 is a diagram describing a read operation using the latch QS for sensing, the latches QM, Q1, and Q2 for storage, and the cache latch Qc. In contrast, FIG. 7 is a diagram describing a read operation using the latch QS for sensing and the cache latch Qc.

Referring to FIG. 7, when a first read command CMD1 is received, a currently selected word line s_WL may be sequentially provided with the seventh read voltage VR7 and the third read voltage VR3. At this time, unselected word lines uns_WL may be provided with a pass voltage. Furthermore, the sensed MSB of a previous memory cell may be output from the cache latch Qc. The LSB of the currently selected memory cell may be sensed by the latch QS for sensing and stored in the cache latch Qc.

A second read command CMD2 may be received prior to the first check point. When the second read command CMD2 is received prior to the first check point, the unselected word lines uns_WL may be continuously provided with the pass voltage. The selected word line s_WL may be sequentially provided with the sixth read voltage VR6, the fourth read voltage VR4, and the second read voltage VR2 for determining the CSB of the currently selected memory cell. At this time, after the first check point, the LSB that has been stored in the cache latch Qc may be output to the outside of the page buffer PB. Furthermore, the CSB of the currently selected memory cell may be sensed by the latch QS for sensing and stored in the cache latch Qc.

A third read command CMD3 may be received prior to the second check point. When the third read command CMD3 is received prior to the second check point, the unselected word lines uns_WL may be continuously provided with the pass voltage. The selected word line s_WL may be sequentially provided with the fifth read voltage VR5 and the first read voltage VR1 for determining the MSB of the currently selected memory cell. At this time, after the second check point, the CSB that has been stored in the cache latch Qc may be output to the outside of the page buffer PB. Furthermore, the MSB of the currently selected memory cell may be sensed by the latch QS for sensing and stored in the cache latch Qc.

A fourth read command CMD4 may be received prior to the third check point. When the fourth read command CMD4 is received prior to the third check point, the voltage levels of the currently selected word line s_WL and the unselected word lines uns_WL may be precharged to a specific voltage level. Furthermore, a next selected word line may be sequentially provided with at least one of the first to seventh read voltages VR1 to VR7, and unselected word lines may be provided with a pass voltage. Furthermore, the MSB of a memory cell, which has been stored in the cache latch Qc may be output to the outside of the page buffer PB.

As described above, in a read operation of the semiconductor device according to an embodiment of the present disclosure, when multiple bits stored in one memory cell are sequentially output by a read command that has been received prior to each check point, a pass voltage may be continuously provided to unselected word lines without precharging word lines, and read voltages for determining each of the multiple bits may be sequentially provided to a selected word line. Furthermore, the latch for sensing may sense data by the read command that has been received prior to the check point, and the sensed data may be stored in the cache latch and output. Accordingly, multi-bit data stored in a memory cell can be sequentially read.

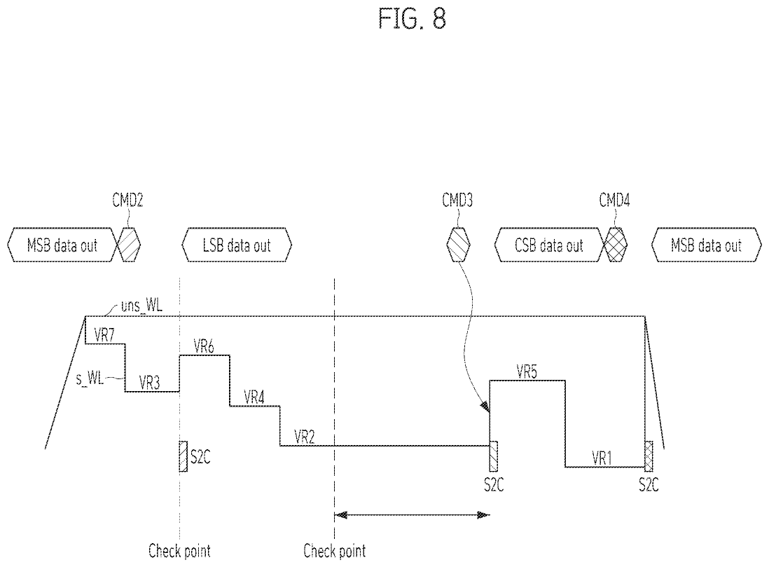

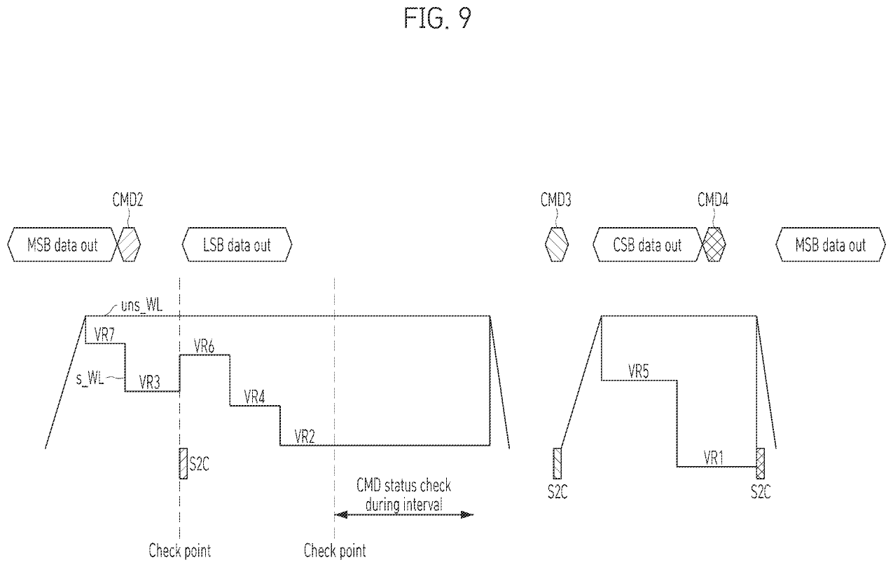

FIGS. 8 and 9 are diagrams for describing an operation of reading data of a memory cell in which 3-bit data have been stored. In this case, a case in which the semiconductor device consecutively receives read commands to instruct to output data of the LSB, the CSB, and the MSB that have been stored in a memory cell, but receives at least one of the read commands that are consecutively received after a check point is described. A description of the read operations in FIGS. 8 and 9 may be the same as that of the read operations in FIGS. 6 and 7 except timing at which the third read command CMD3 is received. Accordingly, in the description of FIGS. 8 and 9, the timing at which the third read command CMD3 is received is described, and a description of other operations may be substituted with the description of the operations in FIGS. 6 and 7.

For example, as illustrated in FIG. 8, the third read command CMD3 may be received after the second check point. This case may be a case in which the third read command CMD3 is received within a set time after the second check point. In such a case, each of the unselected word lines uns_WL and the selected word line s_WL may maintain a voltage level until the third read command CMD3 is received. Furthermore, after the third read command CMD3 is received, the selected word line s_WL may be sequentially provided with the fifth read voltage VR5 and the first read voltage VR1. The CSB that has been sensed by the second read command CMD2 may be moved from the latch Q1 for storage to the cache latch Qc, and may be output to the outside of the page buffer PB.

As illustrated in FIG. 9, the third read command CMD3 may be received after a time greater than a set time after the second check point. In such a case, when the set time after the second check point elapses, all of the unselected word lines uns_WL and the selected word line s_WL may be precharged until the third read command CMD3 is received. Thereafter, when the third read command CMD3 is received, the unselected word lines uns_WL may be provided with a pass voltage, and the selected word line s_WL may be sequentially provided with the fifth read voltage VR5 and the first read voltage VR1. Furthermore, the CSB that has been sensed by the second read command CMD2 may be moved from the latch Q1 for storage to the cache latch Qc, and may be output to the outside of the page buffer PB.

As described above, the semiconductor device according to an embodiment of the present disclosure can reduce power consumption for the semiconductor device by precharging word lines until a next read command is received when a time between pieces of timing at which consecutive read commands are received is greater than a set time if the consecutive read commands for a memory cell in which multiple bits have been stored are received.

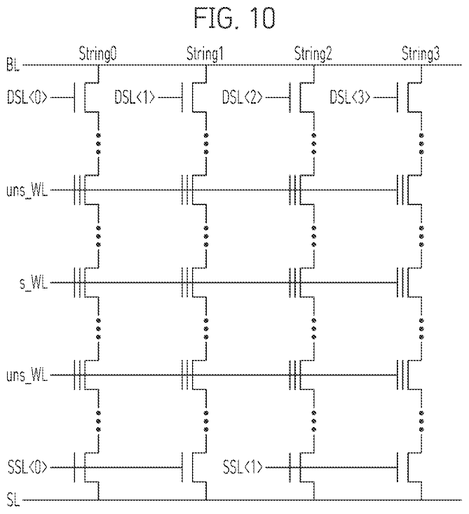

FIG. 10 is a diagram illustrating a configuration of a semiconductor device according to another embodiment of the present disclosure.

FIG. 10 may be a diagram for describing a multi-string structure in which a plurality of memory strings String0, String1, String2, and String3 has been connected to one bit line.

Referring to FIG. 10, the plurality of memory strings String0, String1, String2, and String3 may be connected between one bit line BL and a source line SL. In this case, the plurality of memory strings String0, String1, String2, and String3 may include a first memory string String0, a second memory string String1, a third memory string String2, and a fourth memory string String3.

For example, the first memory string String0 may include a drain selection transistor, a plurality of memory cells, and a source selection transistor that are connected in series between the bit line BL and the source line SL. In this case, the drain selection transistor of the first memory string String0 may be connected to a first drain selection line DSL<0>, and the source selection transistor of the first memory string String0 may be connected to a first source selection line SSL<0>. Furthermore, the plurality of memory cells may be connected to a plurality of word lines including a selected word line Sel. WL and unselected word lines Unsel.WL.

The second memory string String1 may include a drain selection transistor, a plurality of memory cells, and a source selection transistor that are connected in series between the bit line BL and the source line SL. In this case, the drain selection transistor of the second memory string String1 may be connected to a second drain selection line DSL<1>. The source selection transistor of the second memory string String1 may be connected to the first source selection line SSL<0>. Furthermore, the plurality of memory cells may be connected to the plurality of word lines including the selected word line Sel.WL and the unselected word lines Unsel.WL.

The third memory string String2 may include a drain selection transistor, a plurality of memory cells, and a source selection transistor that are connected in series between the bit line BL and the source line SL. In this case, the drain selection transistor of the third memory string String2 may be connected to the third drain selection line DSL<2>. The source selection transistor of the third memory string String2 may be connected to the second source selection line SSL<1>. Furthermore, the plurality of memory cells may be connected to the plurality of word lines including the selected word line Sel.WL and the unselected word lines Unsel.WL.

The fourth memory string String3 may include a drain selection transistor, a plurality of memory cells, and a source selection transistor that are connected in series between the bit line BL and the source line SL. In this case, the drain selection transistor of the fourth memory string String3 may be connected to the fourth drain selection line DSL<3>. The source selection transistor of the fourth memory string String3 may be connected to the second source selection line SSL<1>. Furthermore, the plurality of memory cells may be connected to the plurality of word lines including the selected word line Sel. WL and the unselected word lines Unsel.WL.

The semiconductor device constructed above according to another embodiment of the present disclosure may select the first memory string String0 by enabling the first drain selection line DSL<0> and the first source selection line SSL<0>, and may select the second memory string String1 by enabling the second drain selection line DSL<1> and the first source selection line SSL<0>. Furthermore, the semiconductor device may select the third memory string String2 by enabling the third drain selection line DSL<2> and the second source selection line SSL<1>, and may select the fourth memory string Stirng3 by enabling the fourth drain selection line DSL<3> and the second source selection line SSL<1>.

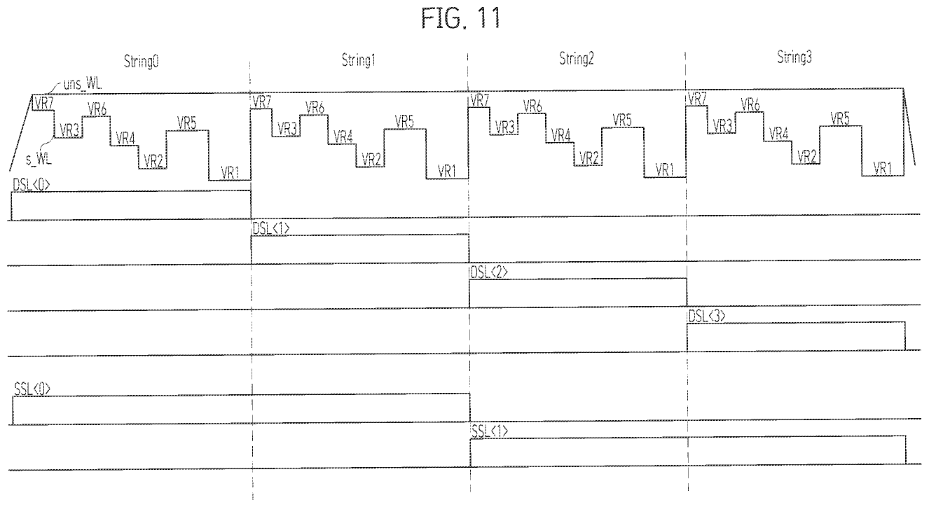

FIG. 11 is a diagram for describing an operation of the semiconductor device according to another embodiment of the present disclosure.

Referring to FIGS. 10 and 11, the semiconductor device according to another embodiment of the present disclosure may perform consecutive read operations on a plurality of memory strings, for example, the first to fourth memory strings String0, String1, String2, and String3 that are connected between one bit line BL and the source line SL.

In the state in which the voltage levels of the unselected word lines uns_WL, among the plurality of word lines, have been driven to a pass voltage, in order to select the first memory string String0, the first drain selection line DSL<0> and the first source selection line SSL<0> may be enabled. Furthermore, in order to consecutively read 3-bit data of a memory cell that is controlled by the selected word line s_WL, among the memory cells included in the first memory string String0, the selected word line s_WL may be sequentially provided with the seventh read voltage VR7, the third read voltage VR3, the sixth read voltage V6, the fourth read voltage VR4, the second read voltage VR2, the fifth read voltage VR5, and the first read voltage VR1. In this case, the seventh read voltage VR7 and the third read voltage VR3 may each be a voltage that is provided to determine the MSB of the memory cell. The sixth read voltage VR6, the fourth read voltage VR4, and the second read voltage VR2 may each be a voltage that is provided to determine the CSB of the memory cell. The fifth read voltage V5 and the first read voltage VR1 may each be a voltage that is provided to determine the LSB of the memory cell.

After the consecutive read operations for multiple bits (e.g., 3 bits) stored in the memory cell of the first memory string String0 are completed, the second memory string String1 may be selected. At this time, the voltage levels of the unselected word lines uns_WL that are driven to the pass voltage may be maintained. In order to select the second memory string String1, in the state in which the first drain selection line DSL<0> has been disabled and the first source selection line SSL<0> has been enabled, the second drain selection line DSL<1> may be enabled. Furthermore, in order to consecutively read 3-bit data of a memory cell that is controlled by the selected word line s_WL, among the memory cells included in the second memory string String1, the selected word line s_WL may be sequentially provided with the seventh read voltage VR7, the third read voltage VR3, the sixth read voltage V6, the fourth read voltage VR4, the second read voltage VR2, the fifth read voltage VR5, and the first read voltage VR1.

After the consecutive read operations for multiple bits (e.g., 3 bits) stored in the memory cell of the second memory string String1 are completed, the third memory string String2 may be selected. At this time, the voltage levels of the unselected word lines uns_WL that are driven to the pass voltage may be maintained. In order to select the third memory string String2, the second drain selection line DSL<1> and the first source selection line SSL<0> may be disabled, and the second source selection line SSL<1> and the third drain selection line DSL<2> may be enabled. Furthermore, in order to consecutively read 3-bit data of a memory cell that is controlled by the selected word line s_WL, among the memory cells included in the third memory string String2, the selected word line s_WL may be sequentially provided with the seventh read voltage VR7, the third read voltage VR3, the sixth read voltage V6, the fourth read voltage VR4, the second read voltage VR2, the fifth read voltage VR5, and the first read voltage VR1.

After the consecutive read operations for multiple bits (e.g., 3 bits) stored in the memory cell of the third memory string String2 are completed, the fourth memory string String3 may be selected. At this time, the voltage levels of the unselected word lines uns_WL that are driven to the pass voltage may be maintained. In order to select the fourth memory string String3, in the state in which the third drain selection line DSL<2> has been disabled and the second source selection line SSL<1> has been enabled, the fourth drain selection line DSL<3> may be enabled. Furthermore, in order to consecutively read 3-bit data of a memory cell that is controlled by the selected word line s_WL, among the memory cells included in the fourth memory string String3, the selected word line s_WL may be sequentially provided with the seventh read voltage VR7, the third read voltage VR3, the sixth read voltage V6, the fourth read voltage VR4, the second read voltage VR2, the fifth read voltage VR5, and the first read voltage VR1.

As described above, the semiconductor device according to an embodiment of the present disclosure can consecutively output multi-bit data that have been stored in a memory cell by sequentially providing a selected word line with a plurality of read voltages for determining the multiple bits in the state in which a pass voltage has been provided to unselected word lines after the start of a read operation. Furthermore, even in the case of a structure including a plurality of memory strings that are connected to one bit line and a source line, the semiconductor device can select each memory string and sequentially provide a selected word line with a plurality of read voltages for determining multiple bits whenever the memory string is selected in the state in which unselected word lines have been provided with a pass voltage. Accordingly, the semiconductor device can consecutively output multi-bit data that have been stored in a memory cell for each memory string.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure. Furthermore, the embodiments may be combined to form additional embodiments.

What is claimed is:

1. A semiconductor device comprising:
at least one memory string that is connected between a bit line and a source line and includes a plurality of memory cells connected to a plurality of word lines; and
a page buffer connected to the bit line and configured to sense data stored in the plurality of memory cells,
wherein multi-bit data stored in a selected memory cell of the plurality of memory cells are consecutively output by sequentially providing a selected word line of the plurality of word lines with read voltages having different levels in a state in which unselected word lines of the plurality of word lines are provided with a pass voltage.

2. The semiconductor device of claim 1, wherein the multi-bit data comprise a most significant bit (MSB), a central significant bit (CSB), and a least significant bit (LSB).

3. The semiconductor device of claim 2, wherein:
the read voltages include first to seventh read voltages having different levels;
each of the seventh read voltage and the third read voltage is used for determining the LSB;
each of the sixth read voltage, the fourth read voltage, and the second read voltage is used for determining the CSB; and
each of the fifth read voltage and the first read voltage is used for determining the MSB.

4. The semiconductor device of claim 3, wherein to sequentially determine the LSB, the CSB, and the MSB stored in the selected memory cell, the selected word line is sequentially provided with the seventh read voltage, the third read voltage, the sixth read voltage, the fourth read voltage, the second read voltage, the fifth read voltage, and the first read voltage in a state in which the unselected word lines are provided with the pass voltage.

5. The semiconductor device of claim 4, wherein:
after the seventh read voltage and the third read voltage are provided to the selected word line, the LSB is determined through the bit line;
after the sixth read voltage, the fourth read voltage, and the second read voltage are provided to the selected word line, the CSB is determined through the bit line; and
after the fifth read voltage and the first read voltage are provided to the selected word line, the MSB is determined through the bit line.

6. The semiconductor device of claim 5, wherein:
the page buffer comprises a cache latch, a latch for storage, and a latch for sensing;
when the seventh read voltage and the third read voltage are provided to the selected word line, the latch for sensing senses the LSB;
when the sixth read voltage, the fourth read voltage, and the second read voltage are provided to the selected word line, the latch for sensing senses the CSB; and
when the fifth read voltage and the first read voltage are provided to the selected word line, the latch for sensing senses the MSB.

7. The semiconductor device of claim 3, wherein:
the at least one memory string comprises a first memory string and a second memory string that share the plurality of word lines and the source line; and
in a state in which the unselected word lines are provided with the pass voltage, the LSB, the CSB, and the MSB stored in a selected memory cell of the first memory string are sequentially determined, and the LSB, the CSB, and the MSB stored in a selected memory cell of the second memory string are determined.

8. The semiconductor device of claim 7, wherein:
when the LSB, the CSB, and the MSB stored in the selected memory cell of the first memory string are sequentially determined, the selected word line is sequentially provided with the seventh read voltage, the third read voltage, the sixth read voltage, the fourth read voltage, the second read voltage, the fifth read voltage, and the first read voltage; and
when the LSB, the CSB, and the MSB stored in the selected memory cell of the second memory string are determined, the selected word line is sequentially provided with the seventh read voltage, the third read voltage, the sixth read voltage, the fourth read voltage, the second read voltage, the fifth read voltage, and the first read voltage.

9. An operating method of a semiconductor device, the operating method comprising:
receiving a read command that instructs to consecutively output multi-bit data stored in a memory cell of a memory string coupled to a plurality of word lines;
providing a pass voltage to unselected word lines of the plurality of word lines until an operation corresponding to the read command is completed; and
sequentially providing a selected word line of the plurality of word lines with read voltages having different levels to sequentially determine the multi-bit data.

10. The operating method of claim 9, wherein the multi-bit data comprise a least significant bit (LSB), a central significant bit (CSB), and a most significant bit (MSB).

11. The operating method of claim 10, wherein:
the read voltages include first to seventh read voltages having different levels; and
each of the seventh read voltage and the third read voltage is used for determining the LSB, each of the sixth read voltage, the fourth read voltage, and the second read voltage is used for determining the CSB, and each of the fifth read voltage and the first read voltage is used for determining the MSB.

12. The operating method of claim 11, wherein sequentially providing the selected word line comprises sequentially providing the selected word line with the seventh read voltage, the third read voltage, the sixth read voltage, the fourth read voltage, the second read voltage, the fifth read voltage, and the first read voltage.

13. The operating method of claim 12, wherein sequentially providing the selected word line comprises:
determining the LSB by sequentially providing the selected word line with the seventh read voltage and the third read voltage;
determining the CSB by sequentially providing the selected word line with the sixth read voltage, the fourth read voltage, and the second read voltage; and
determining the MSB by sequentially providing the selected word line with the fifth read voltage and the first read voltage.

14. An operating method of a semiconductor device, the operating method comprising:
receiving a read command;
checking that the read command is received prior to a check point;
outputting data sensed in a previous read command in response to the checked reception of the read command; and
sensing data by sequentially providing a selected word line with read voltages having different levels in response to the checked reception of the read command.

15. The operating method of claim 14, wherein outputting data comprises outputting data stored in a cache latch included in a page buffer.

16. The operating method of claim 14, wherein sensing data comprises:
providing the selected word line with the read voltages having the different levels in a state in which unselected word lines are provided with a pass voltage; and
sensing data of a memory cell connected to the selected word line by using a latch for sensing included in the page buffer.

17. The operating method of claim 16, wherein sensing data of the memory cell comprises moving, to the latch for storage or a cache latch included in a page buffer, the data sensed by the latch for sensing.

18. The operating method of claim 14, wherein, when the reception of the read command is checked in a state in which a set time after a check point elapses:
unselected word lines and the selected word line are precharged;
the unselected word lines are provided with a pass voltage; and
the selected word line is provided with the read voltages.
